(19) United States
(12) Patent Application Publication
(10) Pub. No.: US 2024/0339299 A1
(43) Pub. Date: Oct. 10, 2024

(54) MICROWAVE ANTENNA, AND POWER SUPPLYING DEVICE AND SUBSTRATE PROCESSING APPARATUS INCLUDING SAME

(71) Applicant: SEMES CO., LTD., Cheonan-si (KR)

(72) Inventors: Yoon Seok CHOI, Cheonan-si (KR); Sun Wook JUNG, Cheonan-si (KR); Youn Gun BONG, Cheonan-si (KR)

(73) Assignee: SEMES CO., LTD., Cheonan-si (KR)

(21) Appl. No.: 18/607,486

(22) Filed: Mar. 17, 2024

(30) Foreign Application Priority Data
Apr. 5, 2023 (KR) 10-2023-0044692

(51) Int. Cl. H01J 37/32

(52) U.S. Cl. CPC H01J 37/3222; H01J 37/32229; H01J 37/32238; H01J 37/3244; H01J 37/32541; H01J 37/3255

(57) ABSTRACT

Proposed are a microwave antenna, and a power supplying device and a substrate processing apparatus including the same, which ensure efficient placement of components while effectively applying power to a plasma chamber. The microwave antenna includes a ring frame, and a plurality of slots provided on an inner wall of the ring frame.

### CROSS REFERENCE TO RELATED APPLICATION

The present application claims priority to Korean Patent Application No. 10-2023-00044692, filed on Apr. 5, 2023, the entire contents of which is incorporated by reference herein for all purposes.

### BACKGROUND OF THE INVENTION

### Field of the Invention

The present disclosure relates to a microwave antenna, and a power supplying device and a substrate processing apparatus including the same.

### Description of the Related Art

Semiconductor manufacturing is a process of manufacturing semiconductor devices on a substrate (e.g., wafer), and includes, for example, exposure, deposition, etching, ion implantation, cleaning, etc. In order to perform each manufacturing process, semiconductor manufacturing equipment for performing individual processes is provided in cleanrooms of a semiconductor manufacturing plant so that a process is performed on a substrate put into the semiconductor manufacturing equipment.

In the semiconductor manufacturing, processes, such as etching and deposition, using plasma are widely used. A plasma processing process is performed by placing a substrate in the lower part of a plasma processing space and applying voltage by an antenna located at the top of the processing space along with the supply of gas for plasma processing. Meanwhile, a technology for radiate microwaves from above to heat treat a substrate is also being introduced.

A power supplying device for processing a substrate is provided at the top of a plasma processing chamber, and the power supplying device may include an upper electrode that applies voltage for plasma processing and a thermal processing device that radiate microwaves for thermal processing. In this case, it is important to arrange the components so that the upper electrode and the thermal processing device do not interfere with each other and power is effectively applied to the plasma processing chamber.

### SUMMARY OF THE INVENTION

Accordingly, the present disclosure has been made keeping in mind the above problems occurring in the related art, and an objective of the present disclosure is to provide a microwave antenna, and a power supplying device and a substrate processing apparatus including the same, which ensure efficient placement of components while effectively applying power to a plasma chamber.

In order to accomplish the above objectives, according to an embodiment of the present disclosure, there is provided a microwave antenna including: a ring frame; and a plurality of slots provided on an inner wall of the ring frame.

According to the embodiment of the present disclosure, the ring frame may have a width of a first length and a height of a second length that is greater than the first length.

According to the embodiment of the present disclosure, the ring frame may be connected to a waveguide through which microwaves are introduced.

According to the embodiment of the present disclosure, the slots may be provided to emit microwaves toward a window located on the inside of the ring frame.

According to an embodiment of the present disclosure, there is provided a power supplying device that provides power to a chamber where a substrate is processed. The device includes: a support member provided at an upper edge of the chamber; a window supported by the support member; and a microwave antenna located between the support member and the window to radiate microwaves to a processing space.

According to the embodiment of the present disclosure, a gas supply line for processing the substrate may be provided inside the support member.

According to the embodiment of the present disclosure, the support member may have a ring shape supported by an inner support of the chamber.

According to the embodiment of the present disclosure, the support member may include: a support ring located on top of the inner support and having a first width; and a support jaw extending inward from a lower part of the support ring and having a second width greater than the first width.

According to the embodiment of the present disclosure, the microwave antenna and the window may be supported by the support jaw.

According to the embodiment of the present disclosure, the microwave antenna may be positioned to be supported on the support jaw while in contact with the support ring, and the window may be supported by the support jaw on the inside of the microwave antenna.

The power supplying device according to the embodiment of the present disclosure may further include: a metal plate placed on top of the window.

According to an embodiment of the present disclosure, there is provided a substrate processing apparatus including: a plasma processing chamber configured to define a plasma processing space; and a power supplying device configured to apply power to the plasma processing space, wherein the power supplying device may include: a support member having a ring shape, provided at an upper edge of the plasma processing chamber, and supported by an inner support; a window supported by the support member; a microwave antenna located between the support member and the window to provide microwaves to the plasma processing space; and an upper electrode in the form of a metal plate disposed on top of the window, wherein the microwave antenna may include: a ring frame having a width of a first length and a height of a second length greater than the first length; and a plurality of slots provided on an inner wall of the ring frame.

According to the present disclosure, by configuring an antenna to apply power toward an inner window, power can be supplied smoothly to a plasma chamber while minimizing interference between components of a power supplying device.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 shows a schematic structure of a substrate processing apparatus according to an embodiment of the present disclosure;

FIGS. 2 and 3 show a power supplying device according to an embodiment of the present disclosure;

FIGS. 4 and 5 show an antenna of a power supplying device according to an embodiment of the present disclosure; and

FIGS. 6 and 7 show a power supplying device according to a comparative example.

### DETAILED DESCRIPTION OF THE INVENTION

Hereinafter, with reference to the accompanying drawings, embodiments of the present disclosure will be described in detail so that those skilled in the art may easily carry out the present disclosure. The present disclosure may be embodied in many different forms and is not limited to the embodiments set forth herein.

In order to clearly describe the present disclosure, parts irrelevant to the description are omitted, and the same reference numerals are assigned to the same or similar components throughout the specification.

In addition, in various embodiments, components having the same configuration will be described only in representative embodiments by using the same reference numerals, and in other embodiments, only configurations different from the representative embodiments will be described.

Throughout the specification, when a part is said to be “connected (or coupled)” to another part, this includes not only the case of being “directly connected (or coupled)” but also “indirectly connected (or coupled)” with another member in between. In addition, when a part “includes”, “has”, or “comprises” a certain part, this means that other components may be further included without excluding other components unless otherwise stated.

Unless otherwise defined, all terms used herein, including technical or scientific terms, have the same meaning as commonly understood by a person skilled in the art. Terms such as those defined in the commonly used dictionaries should be construed as having meanings consistent with the meanings in the context of the related art and shall not be construed in ideal or excessively formal meanings unless expressly defined in this application.

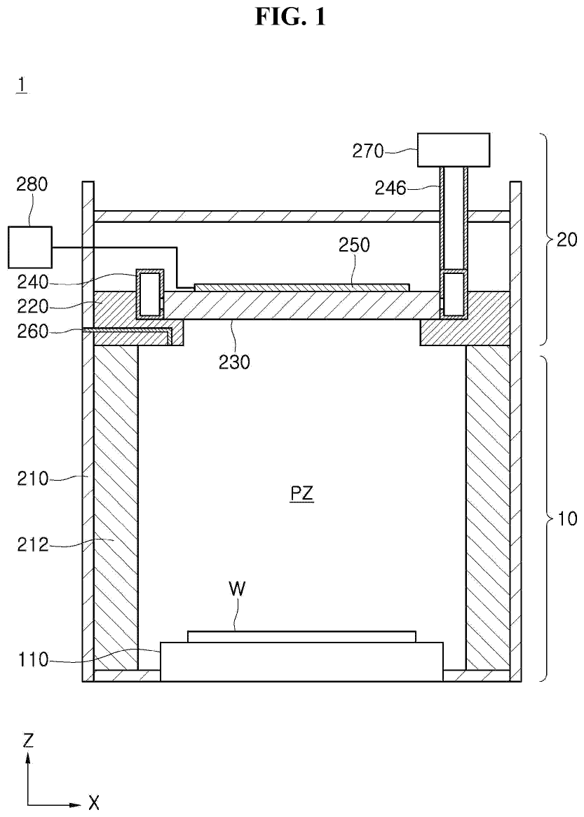

FIG. 1 shows a schematic structure of a substrate processing apparatus 1 according to an embodiment of the present disclosure. Referring to FIG. 1, the substrate processing apparatus 1 may include a plasma processing chamber 10, and a power supplying device 20.

The substrate processing apparatus 1 according to an embodiment of the present disclosure includes: the plasma processing chamber 10 defining a plasma processing space PZ for processing a substrate W; and the power supplying device 20 for applying power to the plasma processing chamber 10. An electrostatic chuck 110 supporting the substrate W is located inside the plasma processing chamber 10, and the substrate W may be located on top of the electrostatic chuck 110. A heater and a cooling passage may be provided inside the electrostatic chuck 110 to control the temperature of the substrate W. In addition, inside the electrostatic chuck 110, a lower electrode for generating plasma may be located in the plasma processing space PZ.

An internal space is created on the outside of the substrate processing apparatus 1 by an outer wall 210, and the plasma processing chamber 10 has an inner support 212 on the inside of the outer wall 210 to seal the plasma processing space PZ. The inner support 212 may support a support member 220 from the bottom. The plasma processing space PZ is formed by the inner support 212, the support member 220, and a window 230.

The power supplying device 20 applies the power required for processing the substrate W in the plasma processing space PZ. The power supplying device 20 may largely include a plasma power supplying device that applies power to form plasma, and a microwave power supplying device that applies microwaves for thermal processing of the substrate W.

The plasma power supplying device may include an upper electrode 250, and an RF power source 280 that provides RF power to the upper electrode 250. Although not specifically shown, a matching circuit for impedance matching and a circuit for power transfer may be provided between the RF power source 280 and the upper electrode 250. The upper electrode 250 may be disposed on top of the window 230. When a processing gas for processing the substrate W is supplied through a gas supply line 260, plasma is formed in the plasma processing space PZ by the upper electrode 250 and the lower electrode provided on the electrostatic chuck 110. The plasma formed by the plasma power supplying device may etch off a specific material of the substrate W.

The microwave power supplying device provides power for thermal processing of the substrate W to the plasma processing space PZ. The microwave power supplying device may include a microwave generation part 270, a microwave waveguide 246, and a microwave antenna 240. Although not specifically shown, the microwave generation part 270 may include a microwave generator, an isolator, a matching circuit, and a mode converter. Microwaves generated by the microwave generation part 270 are transmitted to the microwave antenna 240 through the waveguide 246. The microwave antenna 240 may emit microwaves to the plasma processing space PZ. Microwaves may also be emitted into the normal pressure space above the antenna, but since there is a metal plate in the upper space reflects microwaves, heating due to microwave absorption does not occur. The specific configuration of the microwave antenna 240 and the power supplying device will be described below with reference to the drawings. In this document, microwaves refer to electromagnetic waves with a frequency in the 300 MHz to 300 GHz band, which is shorter than radio waves and longer than infrared waves. Microwaves have the property of penetrating certain substances while causing a reaction with other specific substances, so the microwaves may be used to heat the substrate W.

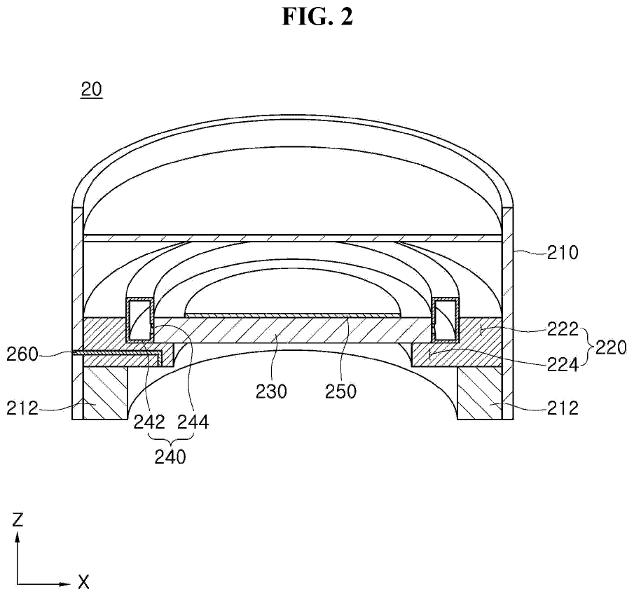

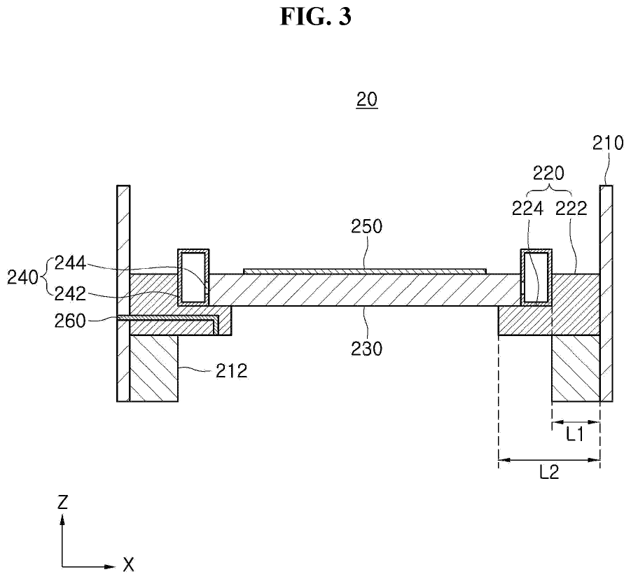

FIGS. 2 and 3 show the power supplying device 20 according to an embodiment of the present disclosure. The power supplying device 20 may provide power to the plasma processing chamber 10. Referring to FIGS. 2 and 3, the power supplying device 20 may be positioned at the top of the plasma processing chamber 10 with respect to the vertical direction (Z direction).

The power supplying device 20 according to an embodiment of the present disclosure includes: the support member 220 provided at the upper edge of the plasma processing chamber 10; the window 230 supported by the support member 220; and the microwave antenna 240 that is located between the support member 220 and the window 230 and that applies microwaves to the plasma processing space. The microwave antenna 240 is located between the support member 220 and the window 230 and emits microwaves toward the window 230, and the microwaves may be propagated to the plasma processing space PZ through window 230.

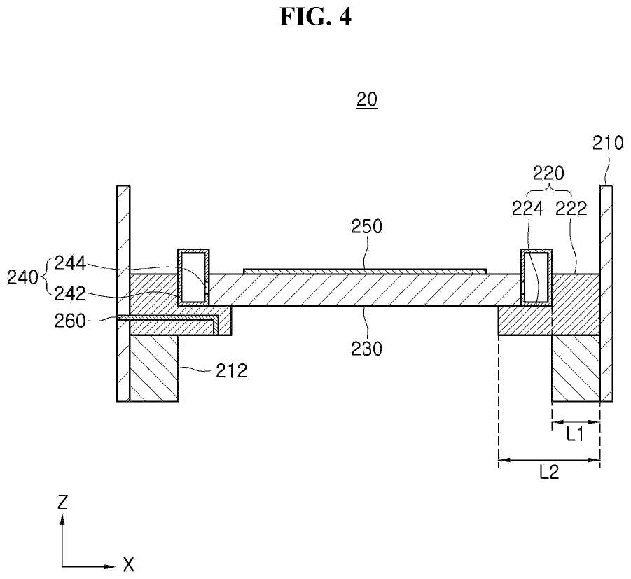

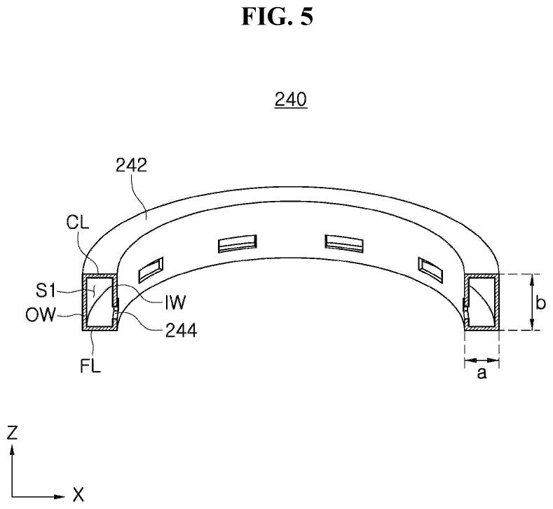

FIG. 4 shows the appearance of the microwave antenna 240 to which the waveguide 246 is connected, and FIG. 5 shows a cross section of the microwave antenna 240 for explanation. The microwave antenna 240 includes: a ring frame 242 having an internal space S1; and a plurality of slots 244 (i.e., openings) formed on an inner wall IW of the ring frame 242. As shown in FIGS. 4 and 5, the microwave antenna 240 is configured to have the empty internal space S1 by a lower surface FL, an upper surface CL, an outer wall OW, and the inner wall IW. The ring frame 242 is a ring-shaped frame with a certain thickness. As shown in FIG. 1, the ring frame 242 of the microwave antenna 240 is connected to the waveguide 246 through which microwaves are introduced, and the microwaves generated by the microwave generation part 270 may be transmitted to the ring frame 242 through the waveguide 246.

The ring frame 242 may have a width of the first length (a) and a height of the second length (b) that is greater than the first length (a) (b>a). That is, the ring frame 242 may have a shape that is longer in the vertical direction (Z direction) than in the horizontal direction (X direction).

The slots 244 formed on the inner wall IW of the ring frame 242 are provided to emit microwaves toward the window 230. For example, the microwave confined in the internal space S1 may be emitted toward the window 230 via the slots 244 (i.e., openings). The slots 244 may be arranged in plural numbers (e.g., 12) at regular intervals on the inner wall IW of the ring frame 242. The microwaves transmitted to the ring frame 242 may be propagated to the window 230 located on the inside through the slots 244.

The ring frame 242 having the slots 244 formed on the inner wall IW thereof may be disposed between the support member 220 and the window 230. The support member 220 may be disposed on the upper perimeter of the plasma processing chamber 10. The support member 220 may have a ring shape supported by the inner support 212 of the plasma processing chamber 10.

The support member 220 may be made of a material through which microwaves can pass, for example, ceramic, quartz, or microwave-transmissive plastic. Meanwhile, the gas supply line is provided inside the support member 220 to supply gas for processing the substrate W. The gas supply line is configured to supply gas for plasma processing and guides the gas supplied from the outside to the plasma processing space PZ.

The support member 220 includes: a support ring 222 located on top of the inner support 212 and having a first width L1; and a support jaw 224 extending inward from the lower part of the support ring 222 and having a second width L2 greater than the first width L1. As shown in FIGS. 2 and 3, the window 230 and the microwave antenna 240 may be supported by the support jaw 224. The microwave antenna 240 may be positioned to be supported by the support jaw 224 while in contact with the support ring 222, and the window 230 may be supported by the support jaw 224 on the inside of the microwave antenna 240.

The window 230 seals the upper part of the plasma processing chamber 10 and is provided to allow microwaves and electromagnetic waves for plasma formation to pass through. The window 230 may be made of quartz material. Referring to FIGS. 2 and 3, the upper electrode 250 in the form of a metal plate is disposed on top of the window 230. The upper electrode 250 may generate electromagnetic force to form plasma in the plasma processing space PZ through electromagnetic coupling with the lower electrode disposed inside the electrostatic chuck 110. In addition, the upper electrode 250 serves to improve microwave efficiency by reflecting microwaves downward and assisting the microwaves to be directed toward the plasma processing space PZ.

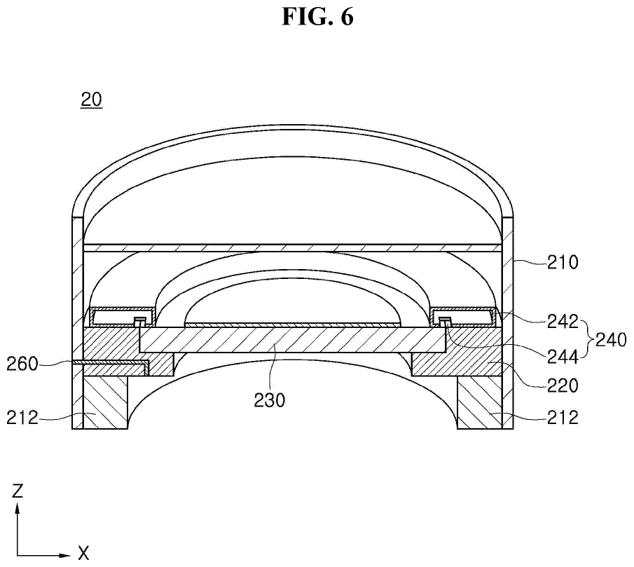

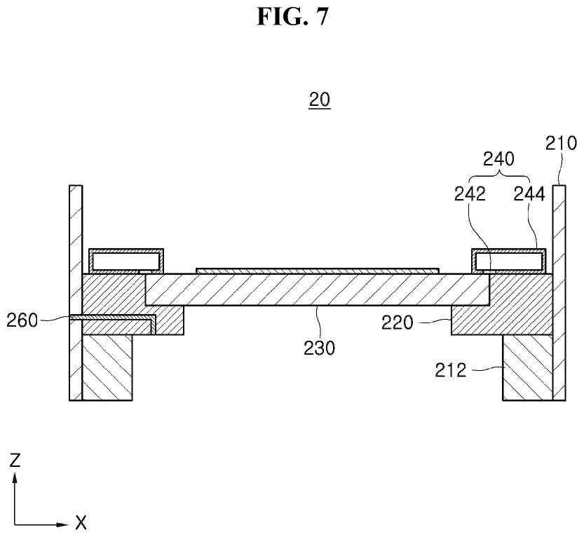

Hereinafter, the effect of the microwave antenna 240 according to the present disclosure will be described by comparing it with the comparative example of FIGS. 6 and 7. In the comparative example shown in FIGS. 6 and 7, the window 230 is supported on the support jaw of the support member 220, and the microwave antenna 240 is located on the upper surfaces of the support member 220 and the window 230. In addition, the microwave antenna 240 has a slot 244 formed on the bottom of the ring frame 242. Furthermore, the microwave antenna 240 has a shape that is wide in the horizontal direction (Z direction) so that the width in the horizontal direction (X direction) is greater than the height in the vertical direction (Z direction).

In the comparative example of FIGS. 6 and 7, since the microwave antenna 240 occupies most of the upper space of the support member 220 and the window 230 in the power supplying device 20, there are limitations in utilizing the internal space of the power supplying device 20.

Although not specifically shown, inside the power supplying device 20, various circuits and components for thermal processing and plasma processing using microwaves need to be placed. Therefore, it is advantageous for the microwave antenna 240 to occupy as little space as possible.

In addition, in the comparative example of FIGS. 6 and 7, since the slot 244 of the microwave antenna 240 faces downward, microwaves are propagated in the downward direction. However, because there are metal parts such as the gas supply line 260 inside the support member 220, reflection of microwaves may occur due to a metal layer. As more microwaves are reflected, the energy transmitted to the substrate W decreases, thus lowering overall energy efficiency.

According to the embodiment of the present disclosure described with reference to FIGS. 2 to 5, the microwave antenna 240 is inserted between the window 230 and the support member 220, and has a width (first length (a)) in the horizontal direction (X direction) that is greater than the height (second length (b)) in the vertical direction (Z direction). In this case, the outer diameter of the microwave antenna 240 is reduced compared to the case of the comparative example. Therefore, the space occupied by the microwave antenna 240 in the power supplying device 20 may be reduced, and space utilization efficiency may be increased.

In addition, according to the embodiment of the present disclosure described with reference to FIGS. 2 to 5, since the slots 244 of the microwave antenna 240 is formed toward the window 230 located on the inside, the microwaves are propagated to the window 230. Because the window 230 is made of quartz material with a high dielectric constant, the wavelength of the propagated microwaves becomes shorter. As the wavelength of the microwaves becomes shorter, the density of the field pattern of the microwaves increases, thereby improving the energy density and uniformity of the microwaves. Microwaves converted in the window 230 are reflected by the metal plate (upper electrode 250) located on top of the window 230 and transmitted to the substrate W of the plasma processing chamber 10.

In conclusion, the microwave antenna 240 according to the embodiment of the present disclosure may improve the energy efficiency transmitted to the substrate W while increasing the space efficiency of the power supplying device 20.

The present embodiments and the drawings accompanying this specification only clearly show some of the technical ideas included in the present disclosure, and it will be apparent that all modifications and specific embodiments that may be easily inferred by those skilled in the art within the scope of the technical idea included in the specification and drawings of the present disclosure are included in the scope of the present disclosure.

Therefore, the spirit of the present disclosure should not be limited to the described embodiments, and it will be said that not only the claims to be described later but also all things that are equivalent to the claims or have equivalent modifications belong to the scope of the present disclosure.

What is claimed is:

1. A microwave antenna comprising:
a ring frame; and
a plurality of slots provided on an inner wall of the ring frame.

2. The microwave antenna of claim 1, wherein the ring frame has a width of a first length and a height of a second length that is greater than the first length.

3. The microwave antenna of claim 1, wherein the ring frame is connected to a waveguide through which microwaves are introduced.

4. The microwave antenna of claim 1, wherein the slots are provided to emit microwaves toward a window located in an inside of the ring frame.

5. A power supplying device providing power to a chamber comprising:
a support member provided at an upper edge of the chamber;
a window supported by the support member; and
a microwave antenna located between the support member and the window to radiate microwaves to a processing space.

6. The device of claim 5, wherein the microwave antenna comprises:
a ring frame; and
a plurality of slots provided on an inner wall of the ring frame.

7. The device of claim 6, wherein the ring frame has a width of a first length and a height of a second length that is greater than the first length.

8. The device of claim 6, wherein the slots are provided to emit the microwaves toward the window.

9. The device of claim 5, wherein a gas supply line for processing a substrate is provided inside the support member.

10. The device of claim 5, wherein the support member has a ring shape supported by an inner support of the chamber.

11. The device of claim 10, wherein the support member comprises:
a support ring located on top of the inner support and having a first width; and
a support jaw extending inward from a lower part of the support ring and having a second width greater than the first width.

12. The device of claim 11, wherein the microwave antenna and the window are supported by the support jaw.

13. The device of claim 12, wherein the microwave antenna is positioned to be supported on the support jaw while in contact with the support ring, and
wherein the support jaw supports the window located in an inside of the microwave antenna.

14. The device of claim 5, further comprising:
a metal plate placed on top of the window.

15. A substrate processing apparatus comprising:
a plasma processing chamber configured to define a plasma processing space; and
a power supplying device configured to apply power to the plasma processing space,
wherein the power supplying device comprises:
a support member provided at an upper edge of the plasma processing chamber, and having a ring shape supported by an inner support;
a window supported by the support member;
a microwave antenna located between the support member and the window to provide microwaves to the plasma processing space; and
an upper electrode in the form of a metal plate disposed on top of the window,
wherein the microwave antenna comprises:
a ring frame having a width of a first length and a height of a second length greater than the first length; and
a plurality of slots provided on an inner wall of the ring frame.

16. The apparatus of claim 15, wherein the slots are provided to emit the microwaves toward the window.

17. The apparatus of claim 15, wherein a gas supply line for processing a substrate is provided inside the support member.

18. The apparatus of claim 15, wherein the support member comprises:
a support ring located on top of the inner support and having a first width; and
a support jaw extending inward from a lower part of the support ring and having a second width greater than the first width.

19. The apparatus of claim 18, wherein the microwave antenna and the window are supported by the support jaw.

20. The apparatus of claim 19, wherein the microwave antenna is positioned to be supported on the support jaw while in contact with the support ring, and
wherein the support jaw supports the window located in an inside of the microwave antenna.
